(19) United States
(12) Patent Application Publication
(10) Pub. No.: US 2013/0168869 A1
(43) Pub. Date: Jul. 4, 2013

(54) Metal Layout of an Integrated Power Transistor and the Method Thereof

(71) Applicant: Peng Xu, Los Altos, CA (US)

(72) Inventor: Peng Xu, Los Altos, CA (US)

(21) Appl. No.: 13/339,005

(22) Filed: Dec. 28, 2011

(51) Int. Cl. H01L 23/522; H01L 21/768

(52) U.S. Cl. 257/774; 438/637; 257/E23.145; 257/E21.577

(57) ABSTRACT

The present disclosure discloses a metal layout of an integrated power transistor. The metal layout comprises a 1^{st} metal layer, a 2^{nd} metal layer, and a 3^{rd} metal layer. The metal layout couples the 1^{st} metal layer to the 2^{nd} metal layer through vias, and couples the 2^{nd} metal layer to the 3^{rd} metal layer through super vias. By such interconnection, the metallization resistance is highly reduced by using thick 2^{nd} and 3^{rd} metal layers.

### TECHNICAL FIELD

The technology described in this patent document relates generally to metal layout and interconnection of integrated power transistors.

### BACKGROUND

For power MOSFETs used in low voltage high current switching regulators, the metallization connection between each transistor cell to package terminals or pins contribute more than 20% of total Ron resistance. So reducing the metallization resistance is important in order to improve the performance. Conventional technique uses four or more metal layers to reduce the metallization connection, which increases cost.

FIG. 1 illustrates a schematic exploded perspective view of a prior art integrated circuit structure with three metal layers. The structure 10 includes a substrate 20, a first conductive layer 30, a second conductive layer 40 over the first conductive layer 30, and a third conductive layer 50 over the second conductive layer 40, wherein the first conductive layer 30 is formed directly on the substrate 20. The integrated circuit structure has an insulation layer between the first conductive layer 30 and the second conductive layer 40, and also between the second conductive layer 40 and the third conductive layer 50.

The first conductive layer 30 includes a first region 32a and a second region 32b. The first region 32a includes a conductive sheet 34a with periodically spaced apertures 36a and conductive islands 38a formed in each aperture 36a. Similarly, the second region 32b includes a conductive sheet 34b with periodically spaced apertures 36b and conductive islands 38b formed in the aperture 36b.

The integrated circuit structure couples the electrical islands to the conductive planes of the second conductive layer with short vertical interconnects, while the continues metal sheets of the first conductive layers are connected to the conductive planes of the third conductive layer with longer vertical interconnects. However, because such interconnects are rather small due to small size of conductive islands 38a, thin conductive layers have to be used (e.g. the first conductive layer 20 has a typical thickness of 0.5 μm, the second conductive layer 40 has a typical thickness of 0.5 μm, and the third conductive layer 50 has a typical thickness of 3 μm), and there is still high parasitic resistance, which generates additional power loss and reduces efficiency.

### SUMMARY

It is an object of the present disclosure to provide a metal layout of an integrated power transistor, which solves above problems.

In accomplishing the above and other objects, there has been provided, in accordance with an embodiment of the present disclosure, a metal layout of an integrated power transistor, comprising: a 1st metal layer, a 2nd metal layer, and a 3rd metal layer, wherein the 1st metal layer is coupled to the 2nd metal layer through vias, while the 2nd metal layer is coupled to the 3rd metal layer through super vias.

In addition, there has been provided, in accordance with an embodiment of the present disclosure, a method for a metal layout of an integrated power transistor, comprising: forming a 1st metal layer; forming a 2nd metal layer; coupling the 1st metal layer to the 2nd metal with vias; forming a 3rd metal layer; and coupling the 2nd metal layer to the 3rd metal with super vias.

### BRIEF DESCRIPTION OF THE DRAWINGS

FIG. 1 illustrates a schematic exploded perspective view of a prior art integrated circuit structure.

FIG. 2 illustrates a schematic top view of the 1^{st} metal layer M1 of an integrated power transistor in accordance with an embodiment of the present disclosure.

FIG. 3 illustrates a schematic top view of the 2^{nd} metal layer M2 of an integrated power transistor in accordance with an embodiment of the present disclosure.

FIG. 4 illustrates a schematic top view of M1-to-M2 vias in accordance with an embodiment of the present disclosure.

FIG. 5 illustrates an amplified schematic top view of M1-to-M1 vias in accordance with an embodiment of the present disclosure.

FIG. 6 illustrates a schematic top view of the 3^{rd} metal layer M3 of an integrated power transistor in accordance with an embodiment of the present disclosure.

FIG. 7 illustrates a schematic top view of M2-to-M3 super vias in accordance with an embodiment of the present disclosure.

FIG. 8 illustrates a schematic flowchart of a method for a metal layout of an integrated power transistor in accordance with an embodiment of the present disclosure.

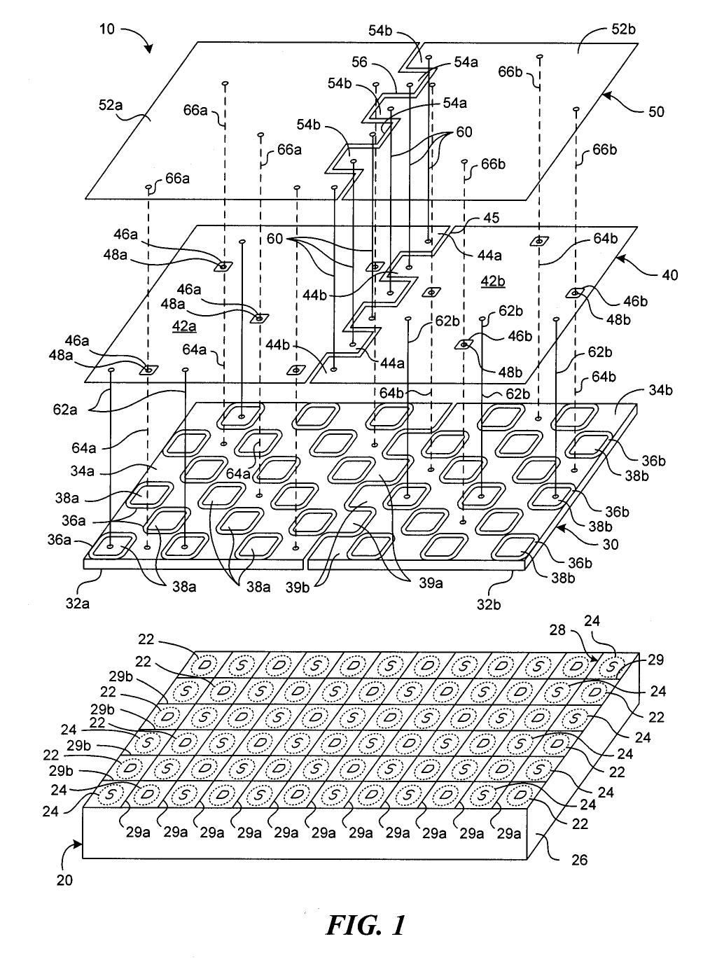

The use of the similar reference label in different drawings may indicate the same or like components.

### DETAILED DESCRIPTION

Embodiments of circuits for metal layout and interconnection of an integrated power transistor are described in detail herein. In the following description, some specific details, such as example circuits for these circuit components, are included to provide a thorough understanding of embodiments of the disclosure. One skilled in relevant art will recognize, however, that the disclosure can be practiced without one or more specific details, or with other methods, components, materials, etc.

The following embodiments and aspects are illustrated in conjunction with circuits and methods that are meant to be exemplary and illustrative. In various embodiments, the above problem has been reduced or eliminated, while other embodiments are directed to other improvements.

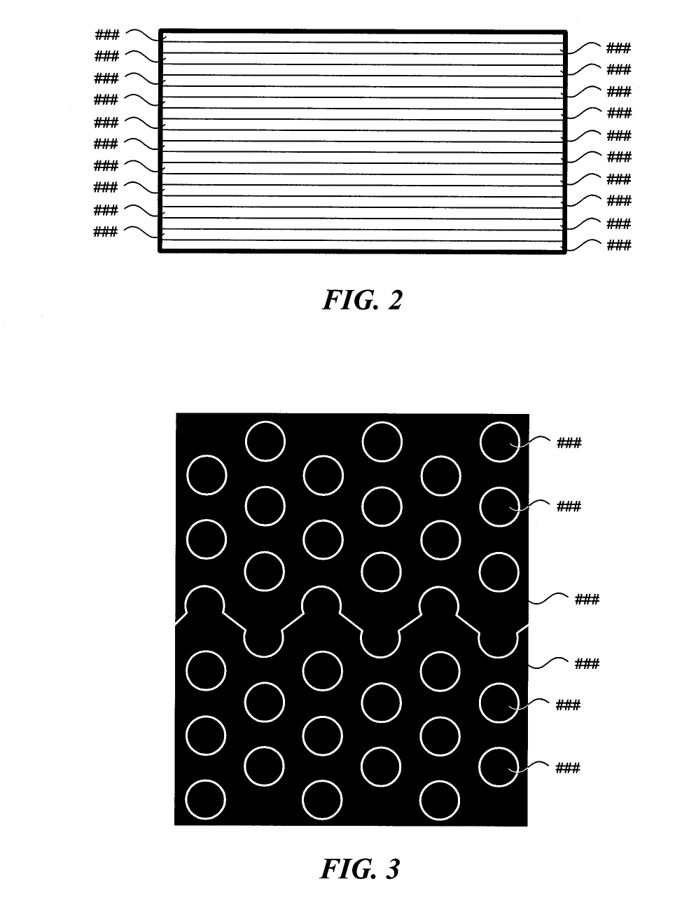

FIG. 2 illustrates a schematic top view of the 1^{st} metal layer M1 of an integrated power transistor in accordance with an embodiment of the present disclosure. In the example of FIG. 2, the 1^{st} metal layer M1 comprises many stripe lines in parallel. The metal stripes are alternatively connected to the source areas or to the drain areas of individual power MOSFET cells. If the switch is to be an N-type MOSFET, then the metal stripes are n-doped source regions or n-doped drain regions in a p-type well or substrate. Alternatively, if the switch is to be a P-type MOSFET, then the metal stripes are p-doped source regions or p-doped drain regions in an n-type well or substrate.

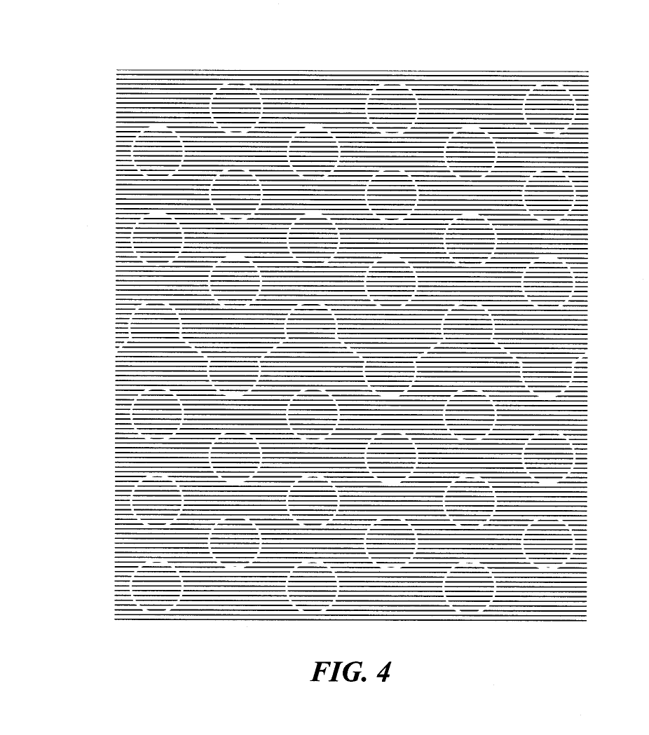

FIG. 3 illustrates a schematic top view of the 2^{nd} metal layer M2 of an integrated power transistor in accordance with an embodiment of the present disclosure. In the example of FIG. 3, the 2^{nd} metal layer M2 comprises two chess-shaped planes: a 1^{st} chess-shaped plane and a 2^{nd} chess-shaped plane. Either chess-shaped plane comprises a lot of holes. Inside the holes of the chess-shaped planes, there is a M2 island. In one embodiment, the 1^{st} chess-shaped plane of M2 connects to M1 stripes at drain potential and the island inside the 1^{st} chess-shaped plane of M2 connects to M1 stripes at source potential; while the 2^{nd} chess-shaped plane of M2 connects to M1 stripes at source potential, and the M2 island inside the 2^{nd} chess-shaped plane of M2 connects to M1 stripes at drain potential. The connections between M1 and M2 are realized through M1-to-M2 vias, as shown in FIG. 4. In one embodiment, the 1^{st} and 2^{nd} chess-shaped planes may have wave-shaped boundary.

FIG. 4 illustrates a schematic top view of M1-to-M2 vias in accordance with an embodiment of the present disclosure.

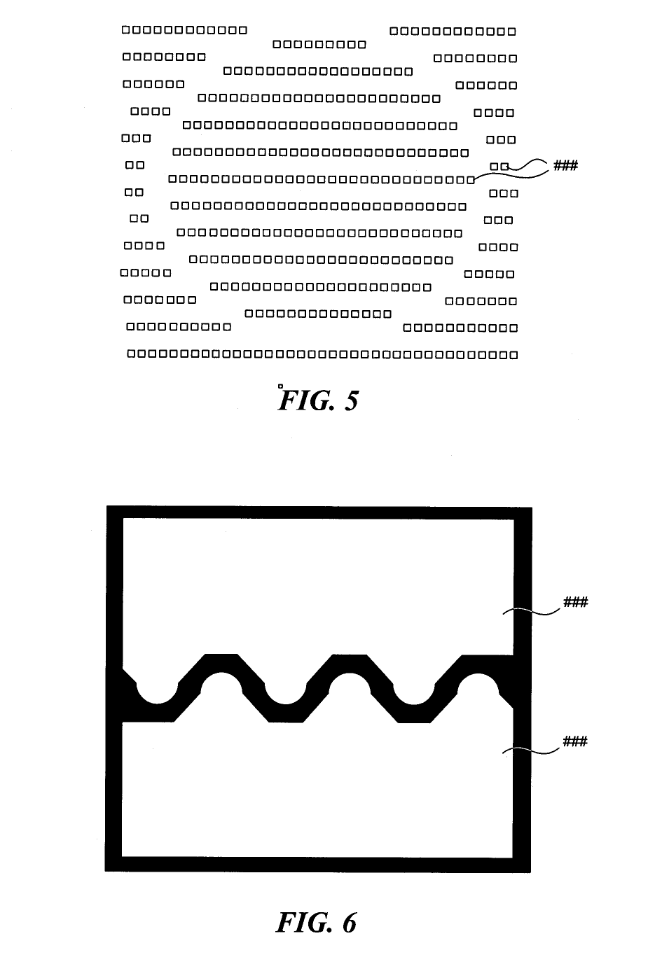

FIG. 5 illustrates an amplified schematic top view of M1-to-M1 vias in accordance with an embodiment of the present disclosure.

FIG. 6 illustrates a schematic top view of the 3^{rd} metal layer M3 of an integrated power transistor in accordance with an embodiment of the present disclosure. In one embodiment, the 3^{rd} metal layer M3 comprises a thick metal layer in package, e.g. the 1^{st} metal layer M1 has a thickness of 0.5-0.6 μm, the 2^{nd} metal layer M2 has a thickness of 3 μm, while the 3^{rd} metal layer has a thickness of 10 μm.

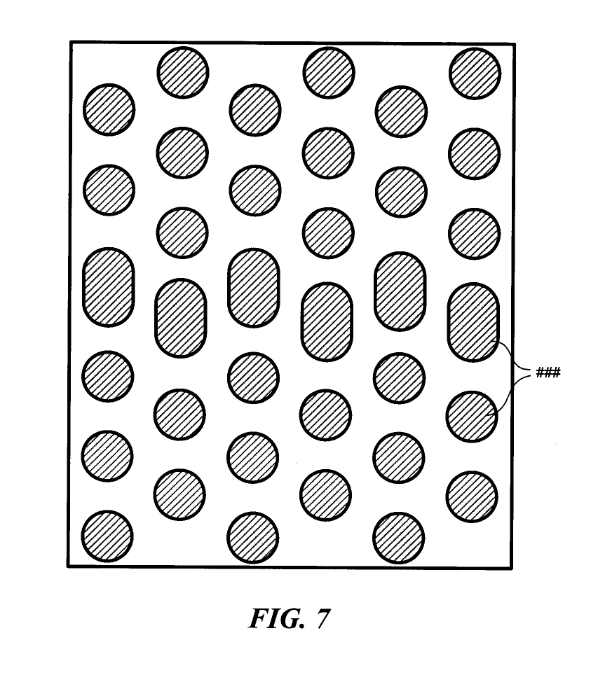

In one embodiment, the 3^{rd} metal layer M3 comprises two solid planes: a 1^{st} solid plane and a 2^{nd} solid plane. The connections between the 2^{nd} metal layer M2 and the 3^{rd} metal layer M3 are realized by M2-to-M3 super vias, as shown in FIG. 7. Large size of super vias makes it possible to use much thicker 3^{rd} metal layers.

FIG. 7 illustrates a schematic top view of M2-to-M3 super vias in accordance with an embodiment of the present disclosure. In one embodiment, the super vias are almost disturbed among the chess-shaped planes and islands in the 2^{nd} metal layer M2. Each island of the 2^{nd} metal layer M2 has one super via. The 1^{st} solid plane of the 3^{rd} metal layer M3 is connected to underneath islands of the 2^{nd} metal layer M2 directly at source potential, and to the 2^{nd} chess-shaped plane of the 2^{nd} metal layer M2 at its edge at source potential. The 2^{nd} solid plane of the 3^{rd} metal layer M3 is connected to underneath islands of the 2^{nd} metal layer M2 directly at drain potential, and to the 1^{st} chess-shaped plane of the 2^{nd} metal layer M2 at its edge at drain potential. In one embodiment, the 1^{st} and the 2^{nd} solid planes of the 3^{rd} metal layer M3 are either directly connected to external terminals/pins of power transistors, or they are the part of external terminals/pins.

Several embodiments of the foregoing power transistor reduce metallization resistance by two metal layers in silicon and one thick metal layer in packaging compared to conventional technique discussed above. Unlike the conventional technique, several embodiments of the foregoing power transistor couple the 1^{st} metal layer to the 2^{nd} metal layer with vias, and couple the 2^{nd} metal layer to the 3^{rd} metal layer with super vias. Large size of super vias makes it possible to use much thicker 3^{rd} metal layers. By such interconnection, the metallization resistance is highly reduced.

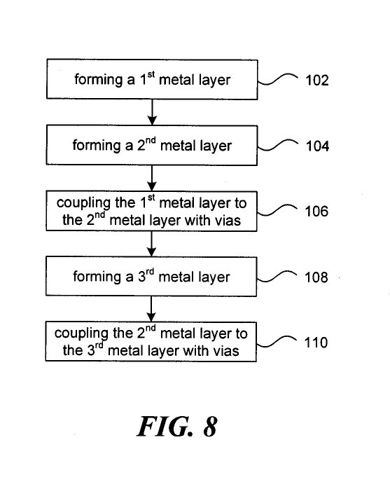

Furthermore, the present disclosure provides a method for metal layout of an integrated power transistor, as shown in FIG. 8. In one embodiment, the method comprises: step 102, forming a 1^{st} metal layer; step 104, forming a 2^{nd} metal layer; step 106, coupling the 1^{st} metal layer to the 2^{nd} metal with vias; step 108, forming a 3^{rd} metal layer; and step 110, coupling the 2^{nd} metal layer to the 3^{rd} metal with super vias.

In one embodiment, the 2^{nd} metal layer comprises a 1^{st} chess-shaped plane and a 2^{nd} chess-shaped plane, wherein either chess-shaped plane comprises holes, and each hole has an island inside it.

In one embodiment, the 1^{st} metal layer comprises metal stripe lines placed in parallel, which are alternatively connected to source or the areas of individual power transistor cells.

In one embodiment, the step of coupling the 1^{st} metal layer to the 2^{nd} metal with vias comprises: coupling the 1^{st} chess-shaped plane of the 2^{nd} metal layer to the stripes of the 1^{st} metal layer at drain potential, coupling the island of the 2^{nd} metal layer to stripes of the 1^{st} metal layer at source potential; coupling the 2^{nd} chess-shaped plane of the 2^{nd} metal layer to the stripes of the 1^{st} metal layer at source potential, and coupling the island of the 2^{nd} metal layer to the stripes of the 1^{st} metal layer at drain potential.

In one embodiment, the 3^{rd} metal layer comprises a thick metal in package.

In one embodiment, the step of forming a 3^{rd} metal layer comprises forming the 3^{rd} metal layer to comprise a 1^{st} solid plane and a 2^{nd} solid plane.

In one embodiment, the step of coupling the 2^{nd} metal layer to the 3^{rd} metal with super vias comprises: coupling the 1^{st} solid plane of the 3^{rd} metal layer to the islands of the 2^{nd} metal layer directly at source potential, and to the 2^{nd} chess-shaped plane of the 2^{nd} metal layer at its edge at source potential; and coupling the 2^{nd} solid plane of the 3^{rd} metal layer to the islands of the 2^{nd} metal layer directly at drain potential, and to the 1^{st} chess-shaped plane of the 3^{rd} metal layer at its edge at drain potential.

This written description uses examples to disclose the disclosure, including the best mode, and also to enable a person skilled in the art to make and use the disclosure. The patentable scope of the disclosure may include other examples that occur to those skilled in the art.

I/We claim:

1. A metal layout of an integrated power transistor, comprising:
a 1^{st} metal layer, a 2^{nd} metal layer, and a 3^{rd} metal layer, wherein the 1^{st} metal layer is coupled to the 2^{nd} metal layer through vias, while the 2^{nd} metal layer is coupled to the 3^{rd} metal layer through super vias.

2. The metal layout of claim 1, wherein the 2^{nd} metal layer comprises a 1^{st} chess-shaped plane and a 2^{nd} chess-shaped plane, wherein either chess-shaped plane comprises holes, wherein each hole has an island inside it.

3. The metal layout of claim 2, wherein the 1^{st} metal layer comprises metal stripe lines placed in parallel, which are alternatively connected to source or the areas of individual power transistor cells.

4. The metal layout of claim 3, wherein the metal stripes are n-doped source regions or n-doped drain regions in a p-type well or substrate.

5. The metal layout of claim 3, wherein the metal stripes are p-doped source regions or p-doped drain regions in an n-type well or substrate.

6. The metal layout of claim 3, wherein
the 1^{st} chess-shaped plane of the 2^{nd} metal layer connects to the stripes of the 1^{st} metal layer at drain potential, and the island of the 2^{nd} metal layer connects to stripes of the 1^{st} metal layer at source potential; and
the 2^{nd} chess-shaped plane of the 2^{nd} metal layer connects to the stripes of the 1^{st} metal layer at source potential, and the island of the 2^{nd} metal layer connects to the stripes of the 1^{st} metal layer at drain potential.

7. The metal layout of claim 2, wherein the 3^{rd} metal layer comprises a 1^{st} solid plane and a 2^{nd} solid plane.

8. The metal layout of claim 7, wherein
the 1^{st} solid plane of the 3^{rd} metal layer is connected to underneath islands of the 2^{nd} metal layer directly at source potential, and to the 2^{nd} chess-shaped plane of the 2^{nd} metal layer at its edge at source potential; and
the 2^{nd} solid plane of the 3^{rd} metal layer is connected to underneath islands of the 2^{nd} metal layer directly at drain potential, and to the 1^{st} chess-shaped plane of the 3^{rd} metal layer at its edge at drain potential.

9. The metal layout of claim 7, wherein the 1^{st} and 2^{nd} solid planes of the 3^{rd} metal layer are directly connected to external terminals of the integrated power transistors.

10. The metal layout of claim 7, wherein the 1^{st} and 2^{nd} solid planes of the 3^{rd} metal layer are the part of external terminals of the integrated power transistors.

11. The metal layout of claim 1, wherein the 3^{rd} metal layer comprises a thick metal in package.

12. The metal layout of claim 11, wherein the 3^{rd} metal layer has a thickness of 10 μm.

13. A method for a metal layout of an integrated power transistor, comprising:
forming a 1^{st} metal layer;
forming a 2^{nd} metal layer;
coupling the 1^{st} metal layer to the 2^{nd} metal with vias;
forming a 3^{rd} metal layer; and
coupling the 2^{nd} metal layer to the 3^{rd} metal with super vias.

14. The method of claim 13, wherein the 2^{nd} metal layer comprises a 1^{st} chess-shaped plane and a 2^{nd} chess-shaped plane, wherein either chess-shaped plane comprises holes, wherein each hole has an island inside it.

15. The method of claim 14, wherein the 1^{st} metal layer comprises metal stripe lines placed in parallel, which are alternatively connected to source or the areas of individual power transistor cells.

16. The method of claim 15, wherein the step of coupling the 1^{st} metal layer to the 2^{nd} metal with vias comprises:
coupling the 1^{st} chess-shaped plane of the 2^{nd} metal layer to the stripes of the 1^{st} metal layer at drain potential, and coupling the island of the 2^{nd} metal layer to stripes of the 1^{st} metal layer at source potential; and
coupling the 2^{nd} chess-shaped plane of the 2^{nd} metal layer to the stripes of the 1^{st} metal layer at source potential, and coupling the island of the 2^{nd} metal layer to the stripes of the 1^{st} metal layer at drain potential.

17. The method of claim 14, wherein the step of forming a 3^{rd} metal layer comprises forming the 3^{rd} metal layer to comprise a thick metal in package.

18. The method of claim 14, wherein the 3^{rd} metal layer comprises a 1^{st} solid plane and a 2^{nd} solid plane.

19. The method of claim 18, wherein the step of coupling the 2^{nd} metal layer to the 3^{rd} metal with super vias comprises:
coupling the 1^{st} solid plane of the 3^{rd} metal layer to the islands of the 2^{nd} metal layer directly at source potential, and to the 2^{nd} chess-shaped plane of the 2^{nd} metal layer at its edge at source potential; and
coupling the 2^{nd} solid plane of the 3^{rd} metal layer to the islands of the 2^{nd} metal layer directly at drain potential, and to the 1^{st} chess-shaped plane of the 3^{rd} metal layer at its edge at drain potential.
